(19) United States
(12) Patent Application Publication
(10) Pub. No.: US 2008/0284526 A1
(43) Pub. Date: Nov. 20, 2008

(54) TUNING CIRCUIT AND METHOD

(76) Inventor: Joseph Hughes, Gilbert, AZ (US)

Correspondence Address: Mr. Jerry Chruma;Semiconductor Components Industries, L.L.C., Patent Administration Dept - MD/A700, P.O. Box 62890, Phoenix, AZ, 85082-2890, US

(21) Appl. No.: 11/749,038

(22) Filed: May 15, 2007

(51) Int. Cl. H03L 7/08

(52) U.S. Cl. 331/16; 331/18; 331/1 A

(57) ABSTRACT

A tuning circuit and a method for setting its tuning voltage. The tuning circuit has a phase frequency detector coupled to a loop filter which is coupled to a voltage controlled oscillator. An output terminal of the voltage controlled oscillator is coupled to an input terminal of the phase frequency detector to form a feedback loop. A state machine is coupled between the phase frequency detector and the voltage controlled oscillator. A switch is coupled between an output terminal of the state machine and the input terminal to the loop filter or between the output terminal of the state machine and the input terminal of the voltage controlled oscillator. Alternatively, a comparator is coupled between an input terminal of the state machine and the output terminal to the loop filter or between the input terminal of the state machine and the output terminal of the phase frequency detector.

### TECHNICAL FIELD

The present invention relates, in general, to electronic circuits and, more particularly, to electronic circuits that include a voltage controlled oscillator.

### BACKGROUND

Phase Locked Loop (“PLL”) systems are used in a variety of applications including radio receivers, mobile communications systems, global positioning satellite systems, satellite receivers, telecommunications systems, instrumentation systems, modems, microprocessors, etc. Typically, a PLL system includes a Voltage Controlled Oscillator (“VCO”) for adjusting the system's frequency of operation. A PLL uses a reference signal and a feedback signal to control the VCO's output signal so that it operates at a frequency and phase that match those of the reference signal. A VCO should have a low gain to achieve a low phase noise performance and to lock to the desired frequency. Although the VCO usually locks to the desired frequency, the voltage on the input terminal to the VCO may be skewed too high or too low, which causes reference spurs in the PLL system, i.e., it causes systematic jitter at the PLL reference frequency which decreases the ability of the PLL system to lock onto the desired frequency.

Accordingly, it would be advantageous to have a PLL system and method that reduces the occurrence of reference spurs. It would be of further advantage for the PLL system to be cost efficient to manufacture.

### BRIEF DESCRIPTION OF THE DRAWINGS

The present invention will be better understood from a reading of the following detailed description, taken in conjunction with the accompanying drawing figures, in which like reference numbers designate like elements and in which:

FIG. 1 is a block diagram of a Phase Locked Loop circuit in accordance with an embodiment of the present invention;

FIG. 2 is a flow diagram for operating the Phase Locked Loop circuit of FIG. 1 in accordance with an embodiment of the present invention;

FIG. 3 is a block diagram of a Phase Locked Loop circuit in accordance with another embodiment of the present invention;

FIG. 4 is a block diagram of a Phase Locked Loop circuit in accordance with another embodiment of the present invention; and

FIG. 5 is a flow diagram for operating the Phase Locked Loop circuit of FIG. 4 in accordance with an embodiment of the present invention.

For simplicity of illustration and ease of understanding, elements in the various figures are not necessarily drawn to scale, unless explicitly so stated. In some instances, well-known methods, procedures, components and circuits have not been described in detail so as not to obscure the present disclosure. The following detailed description is merely exemplary in nature and is not intended to limit the disclosure of this document and uses of the disclosed embodiments. Furthermore, there is no intention to be bound by any expressed or implied theory presented in the preceding text, including the title, technical field, background, or abstract.

### DETAILED DESCRIPTION

Generally, the present invention provides a circuit and a method for reducing the occurrence of reference spurs in Phase Locked Loop (“PLL”) systems by centering the control or tuning voltage, V_{TUNE}, that is input to a Voltage Controlled Oscillator (“VCO”). In accordance with one embodiment, a reference voltage V_{REF1} is used to overdrive the tuning voltage V_{TUNE} that appears at the input terminal of the VCO. Tuning voltage V_{TUNE} causes the VCO to produce an output signal comprising an output voltage and an output frequency. The frequency of the output signal is divided by an integer, n, and transmitted to an input terminal of a phase frequency detector. The phase frequency detector creates a pre-tuning voltage V_{PUMP} which is input into a loop filter. The loop filter outputs the tuning voltage V_{TUNE}, which causes the VCO to generate an output signal. Tuning voltage V_{TUNE} is adjusted by switching in a bank of capacitors, i.e., placing a bank of capacitors in parallel with an LC tank circuit in the VCO or switching out a bank of capacitors, i.e., decoupling a bank of capacitors from the LC tank circuit in the VCO. The VCO generates an updated output signal that is transmitted through a divide by n circuit to the phase frequency detector. In accordance with one embodiment, reference voltage V_{REF1} is decoupled from the PLL system when it is substantially locked.

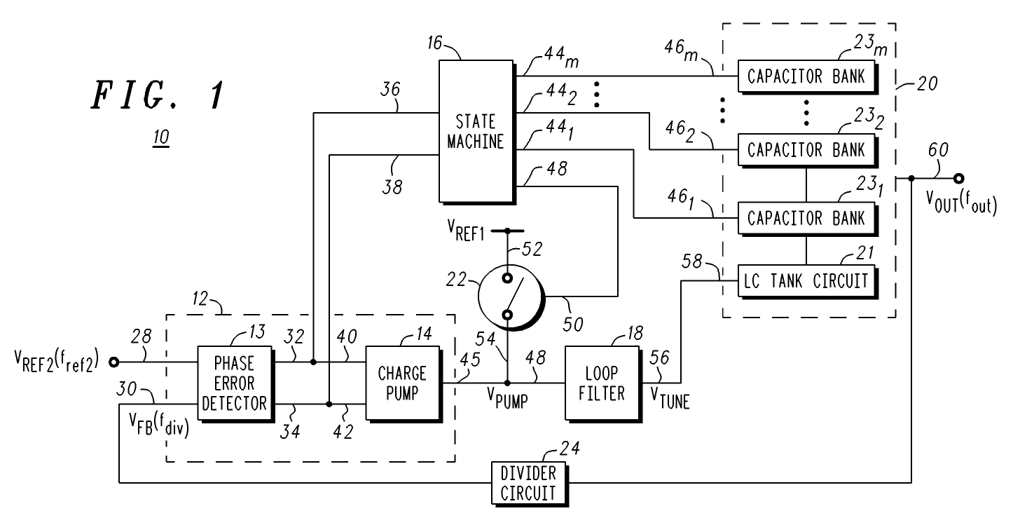

FIG. 1 is a block diagram of a Phase Locked Loop (“PLL”) circuit 10 suitable for manufacture using a monolithic integrated circuit process in accordance with an embodiment of the present invention. PLL circuit 10 is also referred to as a PLL system or a tuning circuit. PLL circuit 10 comprises a Phase Frequency detector (“PFD”) 12 coupled to a state machine 16 and to a loop filter 18. Typically PFD 12 comprises a phase error detector 13 coupled to a charge pump 14. Loop filter 18, also referred to as a Low Pass Filter (“LPF”), is connected to a Voltage Controlled Oscillator (“VCO”) 20. State machine 16 is also connected to VCO 20 and to a switch 22 that is connected to loop filter 18. VCO 20 is coupled to PFD 12 through a divider circuit 24.

More particularly, PFD 12 has an input terminal 28 coupled for receiving a reference signal V_{REF2} having a frequency, f_{ref2}, and an input terminal 30 coupled for receiving a feedback signal VFB having a frequency, f_{div}, from divider circuit 24. PFD 12 has output terminals 32 and 34 connected to input terminals 36 and 38 of state machine 16 and to input terminals 40 and 42 of charge pump 14, respectively. An output terminal 45 of charge pump 14 is connected to an input terminal 48 of loop filter 18. Output terminals 44₁, 44₂, . . . , 44ₘ of state machine 16 are connected to input terminals 46₁, 46₂, . . . , 46ₘ, respectively, of VCO 20, and an output terminal 48 of state machine 16 is connected to a control terminal 50 of switch 22. VCO 20 includes an Inductor-Capacitor (“LC”) tank circuit 21 coupled to one or more banks of switched capacitors 23₁-23ₘ, where m is an integer. By way of example, switch 22 is a three terminal switch having a current carrying electrode 52 coupled for receiving a reference voltage or potential V_{REF1} and a current carrying electrode 54 commonly connected to output terminal 45 of charge pump 14 and to input terminal 48 of loop filter 18. An output terminal 56 of loop filter 18 is connected to an input terminal 58 of VCO 20. An output terminal 60 of VCO 20 serves as an output terminal of PLL circuit 10. Although switch 50 is shown as being coupled before loop filter 18, this is not a limitation of the present invention. For example, current carrying electrode 54 may be commonly connected to output terminal 56 of loop filter 18 and to input terminal 58 of VCO 20. Divider circuit 24 is coupled between output terminal 60 of VCO 20 and input terminal 30 of PFD 12. Preferably, divider circuit 24 is a divide by n circuit, where n is an integer selected by a user.

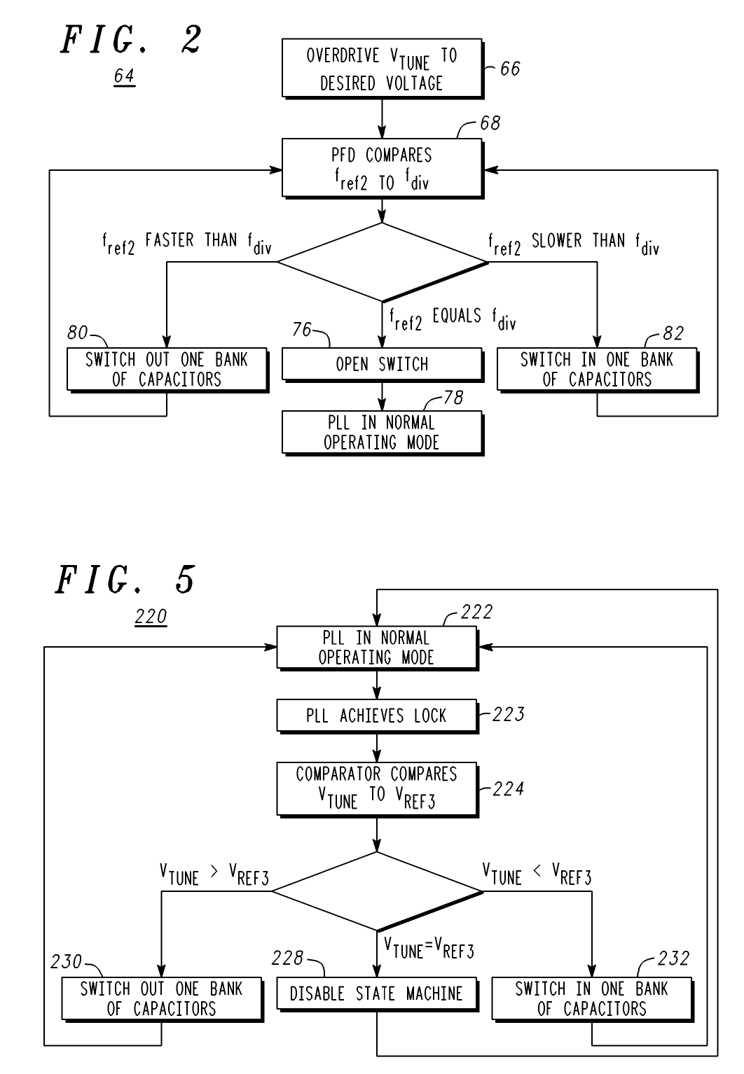

FIG. 2 is a flow diagram 64 illustrating the operation of PLL circuit 10 in accordance with an embodiment of the present invention. During power up of PLL circuit 10 or when a change in the output frequency of VCO 20 is desired, state machine 16 configures switch 22 to connect reference voltage V_{REF1} to input terminal 48. Applying reference voltage V_{REF1} to input terminal 48 overdrives loop filter 18 so that it generates a voltage V_{TUNE} at output terminal 56 (indicated by the box labeled 66). Voltage V_{TUNE} is transmitted to input terminal 58 of VCO 20. In response to voltage V_{TUNE}, VCO 20 generates an output signal V_{OUT} having an output frequency fₒᵤₜ that appears at output terminal 60. Output voltage V_{OUT} appears at the input terminal of divider circuit 24, which generates a feedback signal VFB having a frequency f_{div}. Divider circuit 24 divides frequency fₒᵤₜ by integer n thereby generating feedback signal V_{FB} having frequency f_{div}. Thus, feedback signal V_{FB} has substantially the same amplitude as output signal V_{OUT} but it has a frequency f_{div} which is less than frequency fₒᵤₜ by the factor n.

A reference signal V_{REF2} having a reference frequency f_{ref2} is applied to input terminal 28 and feedback signal V_{FB} having frequency f_{div} is fed back to input terminal 30. Phase error detector 13 compares frequency f_{ref2} to feedback frequency f_{div} and generates a differential phase error signal at output terminals 32 and 34 that indicates the phase difference between signals f_{ref2} and f_{div} (indicated by the box labeled 68). The differential phase error signal is transmitted to input terminals 40 and 42 of charge pump 14 and to input terminals 36 and 38 of state machine 16, respectively. When frequencies f_{ref2} and f_{div} are substantially in phase, the phase error signal is substantially zero and state machine 16 transmits a signal to open switch 22 (indicated by reference number 76). PLL circuit 10 is in a normal operating mode (indicated by the box labeled 78).

In response to the phase error signal having a non-zero value or not being within a predetermined tolerance, i.e., frequency f_{ref2} being substantially unequal to frequency f_{div}, state machine 16 either switches in or switches out one bank of capacitors. If frequency f_{ref2} is faster than frequency f_{div}, state machine 16 switches out one bank of capacitors 23₁-23ₘ within VCO 20, i.e., state machine 16 disconnects a bank of capacitors from LC tank circuit 21 (indicated by the box labeled 80). In response to the new capacitor configuration, VCO 20 generates an updated output voltage V_{OUT} having an updated output frequency f_{OUT}. The updated output voltage V_{OUT} appears at the input of divider circuit 24, which generates an updated feedback signal V_{FB} having an updated frequency f_{div}. Divider circuit 24 divides frequency fₒᵤₜ by integer n thereby generating feedback signal V_{FB} having frequency f_{div}.

Reference signal V_{REF2} having a reference frequency f_{ref2} is applied to input terminal 28 and feedback signal V_{FB} having frequency f_{div} is fed back to input terminal 30 so that phase error detector 13 of PFD 12 can compare them, i.e., the process continues at the stage indicated by the box labeled 68. Phase error detector 13 again compares frequency f_{ref2} to feedback frequency f_{div} and generates a differential phase error signal which is transmitted to input terminals 40 and 42 of charge pump 14 and to input terminals 36 and 38 of state machine 16. In response to frequency f_{ref2} still being substantially greater than feedback frequency f_{div}, i.e., the phase error signal still having a non-zero value or not within a predetermined tolerance, state machine 16 switches out another bank of capacitors 23₁-23ₘ within VCO 20 (indicated by the box labeled 80). The new capacitor configuration causes VCO 20 to generate an updated output voltage V_{OUT} having an updated output frequency f_{OUT}. The updated output voltage V_{OUT} appears at the input terminal of divider circuit 24, which generates a feedback signal V_{FB} having a frequency f_{div}. The process of comparing frequencies f_{ref2} and f_{div} and switching out a bank of capacitors 23₁-23ₘ continues until frequencies f_{ref2} and f_{div} are substantially equal. Once frequencies f_{ref2} and f_{div} are substantially equal, state machine 16 generates a signal to open switch 22 (indicated by the box labeled 76). PLL circuit 10 then enters a normal operating mode (indicated by the box labeled 78).

If frequency f_{ref2} is slower than frequency f_{div}, state machine 16 switches in one bank of capacitors 23₁-23ₘ within VCO 20, i.e., state machine 16 places a bank of capacitors in parallel with LC tank circuit 21 (indicated by the box labeled 82). In response to the new capacitor configuration, VCO 20 generates an updated output voltage V_{OUT} having an updated output frequency f_{OUT}. The updated output voltage V_{OUT} appears at the input of divider circuit 24, which generates a feedback signal V_{FB} having a frequency f_{div}. Divider circuit 24 divides frequency fₒᵤₜ by integer n thereby generating feedback signal V_{FB} having frequency f_{div}.

Reference signal V_{REF2} having a reference frequency f_{ref2} is applied to input terminal 28 and feedback signal V_{FB} having frequency f_{div} is fed back to input terminal 30 so that phase error detector 13 can compare them, i.e., the process continues at the stage indicated by the box labeled 68. Phase error detector 13 again compares frequency f_{ref2} to feedback frequency f_{div} and generates a differential phase error signal which is transmitted to input terminals 40 and 42 of charge pump 14 and to input terminals 36 and 38 of state machine 16. In response to frequency f_{ref2} still being substantially less than feedback frequency f_{div}, i.e., the phase error signal still having a non-zero value or not being within a predetermined tolerance, state machine 16 switches in another bank of capacitors 23₁-23ₘ within VCO 20 (indicated by the box labeled 82). The new capacitor configuration causes VCO 20 to generate an updated output voltage V_{OUT} having an updated output frequency f_{OUT}. The updated output voltage V_{OUT} appears at the input terminal of divider circuit 24, which generates a feedback signal V_{FB} having a frequency f_{div}. The process of comparing frequencies f_{ref2} and f_{div} and switching in a bank of capacitors 23₁-23ₘ continues until frequency f_{ref2} substantially equals feedback frequency f_{div}. Once frequencies f_{ref2} and f_{div} are substantially equal, state machine 16 generates a signal to open switch 22 (indicated by the box labeled 76) and PLL circuit 10 enters a normal operating mode (indicated by the box labeled 78).

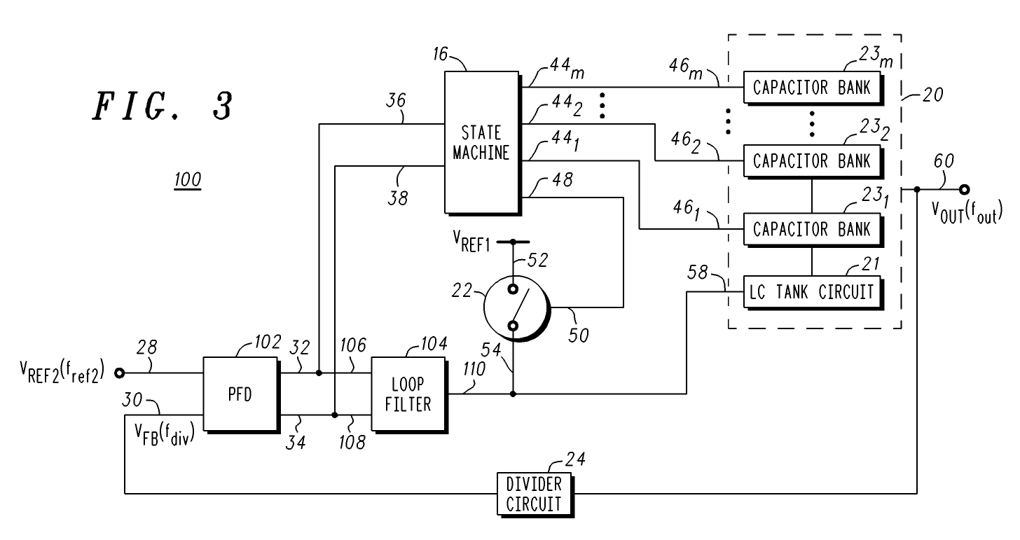

FIG. 3 is a block diagram of a PLL circuit 100 suitable for manufacture using a monolithic integrated circuit process in accordance with another embodiment of the present invention. Like PLL circuit 10, PLL circuit 100 is also referred to as a tuning circuit or a PLL system. PLL circuit 100 comprises a Phase Frequency detector (“PFD”) 102 coupled to a state machine 16 and to a loop filter 104. PLL circuit 100 differs from PLL circuit 10 in that PFD 102 does not include a charge pump. Loop filter 104, also referred to as a Low Pass Filter (“LPF”), is connected to a VCO 20. State machine 16 is also connected to VCO 20 and to a switch 22 that is connected to loop filter 104. VCO 20 is coupled to PFD 102 through a divider circuit 24. More particularly, PFD 102 has an input terminal 28 coupled for receiving a reference signal V_{REF2} having a frequency, f_{ref2}, and an input terminal 30 coupled for receiving a feedback signal V_{FB} having a frequency, f_{div}, from divider circuit 24. PFD 102 has output terminals 32 and 34 connected to input terminals 36 and 38 of state machine 16 and to input terminals 106 and 108 of loop filter 104, respectively. Output terminals 44₁, 44₂, . . . , 44ₘ of state machine 16 are connected to input terminals 46₁, 46₂, . . . , 46ₘ, respectively, of VCO 20 and an output terminal 48 of state machine 16 is connected to a control terminal 50 of switch 22. VCO 20 includes an LC tank circuit 21 coupled to one or more banks of switched capacitors 23₁-23ₘ, where m is an integer. A current carrying electrode 52 of switch 22 is coupled for receiving a reference voltage or potential V_{REF1} and a current carrying electrode 54 is connected to input terminal 58 of VCO 20. Although switch 50 is shown as being coupled after loop filter 104, this is not a limitation of the present invention. For example, current carrying electrode 54 may be connected to input terminals 106 and 108 of loop filter 104. An output terminal 110 of loop filter 104 is also connected to an input terminal 58 of VCO 20. An output terminal 60 of VCO 20 serves as an output terminal of PLL circuit 100. Divider circuit 24 is coupled between output terminal 60 of VCO 20 and input terminal 30 of PFD 102.

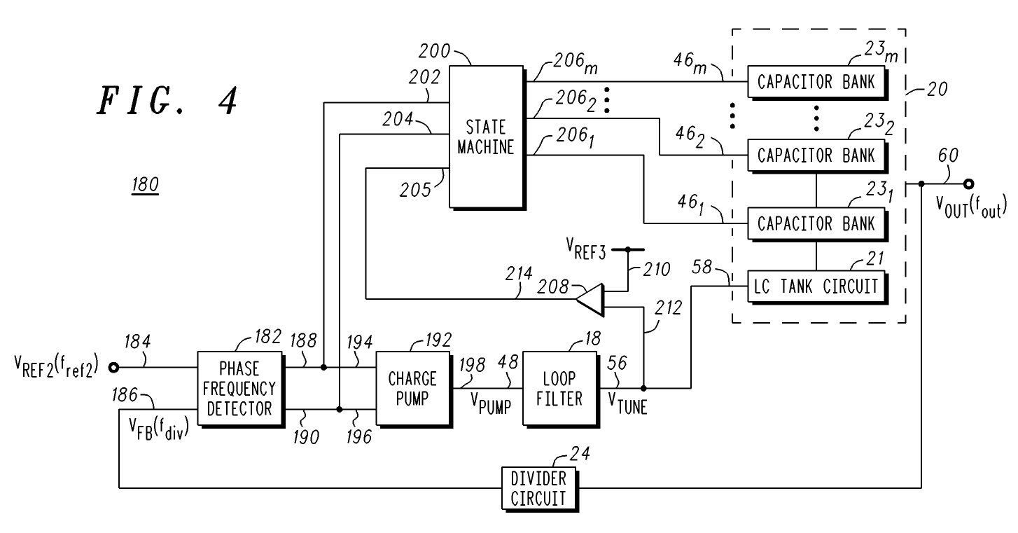

FIG. 4 is a block diagram of a PLL circuit 180 suitable for manufacture using a monolithic integrated circuit process in accordance with another embodiment of the present invention. Like PLL circuits 10 and 100, PLL circuit 180 is also referred to as a tuning circuit or a PLL system. PLL circuit 180 comprises a PFD 182 coupled to a state machine 200 and to a charge pump 192. Charge pump 192 is connected to loop filter 18, which is connected to VCO 20. State machine 200 is also connected to VCO 20. A comparator 208 is coupled between output terminal 56 and an input terminal 205 of state machine 200. VCO 20 is coupled to PFD 182 through a divider circuit 24. PFD 182 has an input terminal 184 coupled for receiving a reference signal V_{REF2} and an input terminal 186 coupled for receiving a feedback signal V_{FB} from divider circuit 24. Reference signal V_{REF2} and feedback signal V_{FB} have frequencies f_{ref2} and f_{div}, respectively. PFD 182 has output terminals 188 and 190 connected to input terminals 202 and 204 of state machine 200 and to input terminals 194 and 196 of charge pump 192, respectively. An output terminal 198 of charge pump 192 is connected to an input terminal 48 of loop filter 18. Output terminals 206₁, 206₂, . . . , 206ₘ of state machine 200 are connected to input terminals 46₁, 46₂, . . . 46ₘ, respectively, of VCO 20. VCO 20 includes an LC tank circuit 21 coupled to one or more banks of switched capacitors 23₁-23ₘ, where m is an integer. An output terminal 214 of comparator 208 is connected to input terminal 205 of state machine 200. An input terminal 212 of comparator 203 is connected to output terminal 56 of loop filter 18 and an input terminal 210 is coupled for receiving a reference voltage or potential V_{REF3}. An output terminal 56 of loop filter 18 is connected to an input terminal 58 of VCO 20. An output terminal 60 of VCO 20 serves as an output terminal of PLL circuit 180. Divider circuit 24 is coupled between output terminal 60 of VCO 20 and input terminal 186 of PFD 182. Preferably, divider circuit 24 is a divide by n circuit, where n is an integer selected by a user.

FIG. 5 is a flow diagram 220 illustrating the operation of PLL circuit 180 in accordance with an embodiment of the present invention. The description of the operation of PLL circuit 180 begins with PLL circuit 180 in a normal operating mode (indicated by the box labeled 222). A reference signal V_{REF2} having a reference frequency f_{ref2} is applied to input terminal 184 and feedback signal V_{FB} having frequency f_{div} is fed back to input terminal 186. Phase frequency detector 182 compares frequency f_{ref2} to feedback frequency f_{div} and generates a differential phase error signal at output terminals 188 and 190 that indicates the phase difference between signals f_{ref2} and f_{div}. The differential phase error signal is transmitted to input terminals 194 and 196 of charge pump 192 and to input terminals 202 and 204 of state machine 200, respectively. If the phase error signal has a substantially zero value, i.e., signals V_{REF2} and V_{FB} are substantially in phase, charge pump 192 generates an output voltage V_{PUMP} and loop filter 18 generates an output voltage V_{TUNE} that substantially equals a reference voltage V_{REF3}. If voltages V_{TUNE} and V_{REF3} are substantially equal, the output signal from comparator 208 disables state machine 200. In this operating mode, PLL circuit 180 is locked or substantially locked (indicated by the box labeled 223). It should be understood that when PLL circuit 180 is locked there may be a small phase difference between reference signal frequency f_{ref2} and feedback signal frequency f_{div}.

Reference voltage or potential V_{REF3} is connected to input terminal 210 of comparator 208 and output terminal 56 of loop filter 18 is connected to input terminal 212 of comparator 208. Thus, loop filter 18 transmits a tuning signal V_{TUNE} to comparator 208 which compares tuning signal V_{TUNE} to reference voltage V_{REF3} (indicated by the box labeled 224).

In response to the phase error signal having a non-zero value or not being within a predetermined tolerance, charge pump 192 either increases or decreases its output voltage V_{PUMP}. The direction that output voltage V_{PUMP} changes, i.e., an increase or a decrease, is dependent on the phase relationship between frequencies f_{ref2} and f_{div}. Voltage V_{PUMP} is input into loop filter 18 which generates a tuning voltage V_{TUNE} at output terminal 56. If voltage V_{TUNE} is greater than reference voltage V_{REF3}, state machine 200 switches out one bank of capacitors 23₁-23ₘ within VCO 20, i.e., state machine 200 disconnects a bank of capacitors from LC tank circuit 21 (indicated by the box labeled 230). An updated output voltage V_{OUT} appears at the input of divider circuit 24, which generates a feedback signal V_{FB} having a frequency f_{div}. Divider circuit 24 divides frequency fₒᵤₜ by integer n thereby generating feedback signal V_{FB} having frequency f_{div}.

In response to the updated output voltage V_{OUT}, loop filter 18 generates an updated tuning voltage V_{TUNE}. If the updated tuning voltage V_{TUNE} is still greater than reference signal V_{REF3}, state machine 200 switches out another bank of capacitors 23₁-23ₘ within VCO 20 (indicated by the box labeled 230). In response to the updated tuning voltage V_{TUNE} and the new capacitor configuration, VCO 20 generates an updated output voltage V_{OUT} having an updated output frequency f_{OUT}. The updated output voltage V_{OUT} appears at the input terminal of divider circuit 24, which generates an updated feedback signal V_{FB} having an updated frequency f_{div}. It should be noted that the updating of signals V_{OUT}, V_{PUMP}, V_{TUNE}, fₒᵤₜ, V_{FB}, and f_{div} occurs before comparator 208 performs any further comparisons. The process of comparing frequencies f_{ref2} and f_{div}, updating voltages V_{PUMP}, V_{TUNE}, V_{FB}, and switching out the bank of capacitors 23₁-23ₘ continues until tuning voltage V_{TUNE} substantially equals reference voltage V_{REF3}. Once voltages V_{TUNE} and V_{REF3} are substantially equal, the output signal from comparator 208 disables state machine 200 (indicated by the box labeled 228) because PLL circuit 180 is locked and enters a normal operating mode (indicated by the box labeled 222).

If tuning voltage V_{TUNE} is less than reference voltage V_{REF3}, state machine 202 switches in one bank of capacitors 23₁-23ₘ within VCO 20, i.e., places a bank of capacitors in parallel with LC tank circuit 21 (indicated by the box labeled 232). In response to tuning voltage V_{TUNE} and the new capacitor configuration, VCO 20 generates an updated output voltage V_{OUT} having an updated output frequency f_{OUT}. The updated output voltage V_{OUT} appears at the input terminal of divider circuit 24, which generates a feedback signal V_{FB} having a frequency f_{div}. Divider circuit 24 divides frequency fₒᵤₜ by integer n thereby generating feedback signal V_{FB} having frequency f_{div}.

Reference signal V_{REF2} having a reference frequency f_{ref2} is applied to input terminal 184 and feedback signal V_{FB} having frequency f_{div} is fed back to input terminal 186 so that phase frequency detector 182 can compare them, i.e., the process continues at the stage indicated by the box labeled 224. Phase frequency detector 182 again compares frequency f_{ref2} to feedback frequency f_{div} and generates a differential phase error signal which is transmitted to input terminals 194 and 196 of charge pump 192 and to input terminals 202 and 204 of state machine 200. In response to the phase error signal having a non-zero value or not being within a predetermined tolerance, charge pump 192 either increases or decreases its output voltage V_{PUMP}. The direction that output voltage V_{PUMP} changes, i.e., an increase or a decrease, is dependent on the phase relationship between frequencies f_{ref2} and f_{div}. Voltage V_{PUMP} is input into loop filter 18 which updates tuning voltage V_{TUNE} at output terminal 56. It should be noted that the updating of tuning voltage V_{TUNE} occurs before comparator 208 performs any further comparisons. If tuning voltage V_{TUNE} is still less than reference voltage V_{REF3}, state machine 200 switches in another bank of capacitors 23₁-23ₘ within VCO 20 (indicated by the box labeled 232). In response to voltage V_{TUNE} and the new capacitor configuration, VCO 20 generates an updated output voltage V_{OUT} having an updated output frequency F_{OUT}. The updated output voltage V_{OUT} appears at the input of divider circuit 24, which generates an updated feedback signal V_{FB} having an updated frequency f_{div}. It should be noted that the updating of signals V_{OUT}, V_{PUMP}, V_{TUNE}, fₒᵤₜ, V_{FB}, f_{div}, V_{PUMP}, and V_{TUNE} occurs before comparator 28 performs any further comparisons. The process of comparing frequencies f_{ref2} and f_{div}, updating voltages V_{PUMP}, T_{UNE}, and V_{FB}, and switching in a bank of capacitors continues until voltage V_{TUNE} substantially equals reference voltage V_{REF3}. Once voltages V_{PUMP}, V_{TUNE}, and V_{REF3} are substantially equal, the output signal from comparator 208 disables state machine 200 (indicated by the box labeled 228) because PLL circuit 180 is locked and enters a normal operating mode (indicated by the box labeled 222).

Although certain preferred embodiments and methods have been disclosed herein, it will be apparent from the foregoing disclosure to those skilled in the art that variations and modifications of such embodiments and methods may be made without departing from the spirit and scope of the invention. It is intended that the invention shall be limited only to the extent required by the appended claims and the rules and principles of applicable law.

What is claimed is:

1. A tuning circuit, comprising:
a phase frequency detector having first and second input terminals and first and second output terminals, the first input terminal coupled for receiving a reference signal;
a loop filter having an input terminal and an output terminal, the input terminal coupled to the first output terminal of the phase frequency detector;
a voltage controlled oscillator having first and second input terminals and an output terminal, the first input terminal coupled to the output terminal of the loop filter;
a divider circuit having an input terminal and an output terminal, the input terminal coupled to the output terminal of the voltage controlled oscillator and the output terminal coupled to the second input terminal of the phase frequency detector; and
a state machine having first and second input terminals and at least one output terminal, the first and second input terminals coupled to first and second output terminals of the phase frequency detector, respectively, and a first output terminal of the at least one output terminal coupled to the second input terminal of the voltage controlled oscillator.

2. The tuning circuit of claim 1, wherein the phase frequency detector comprises a phase error detector coupled to a charge pump and wherein an output terminal of the charge pump serves as the first output terminal of the phase frequency detector.

3. The tuning circuit of claim 1, wherein the voltage controlled oscillator comprises an inductor-capacitor tank circuit coupled to a bank of capacitors, the first output terminal of the at least one output terminal of the state machine coupled to the bank of capacitors.

4. The circuit of claim 1, wherein the voltage controlled oscillator comprises an inductor-capacitor tank circuit coupled to a plurality of banks of capacitors and the state machine has a second output terminal of the at least one output terminal, the first and second output terminals of the state machine coupled to first and second banks of capacitors of the plurality of banks of capacitors, respectively.

5. The circuit of claim 4, wherein the state machine has a third output terminal of the at least one output terminal and further includes a switch coupled between the third output terminal of the state machine and the input terminal of the loop filter.

6. The circuit of claim 1, wherein the state machine has a second output terminal of the at least one output terminal, and further including a switch coupled between the second output terminal of the state machine and the input terminal of the loop filter.

7. The circuit of claim 6, wherein the switch is a three terminal switch having a control terminal and first and second current carrying electrodes, the control terminal coupled to the second output terminal of the state machine, the first current carrying electrode coupled for receiving a first reference potential, and the second current carrying electrode coupled to the input terminal of the loop filter.

8. The circuit of claim 1, wherein the state machine has a plurality of other output terminals, and wherein the voltage controlled oscillator comprises an inductor-capacitor tank circuit coupled to a plurality of banks of capacitors, the first output terminal of the state machine coupled to a first bank of capacitors of the plurality of banks of capacitors and each output terminal of the plurality of other output terminals coupled to a corresponding bank of capacitors of the plurality of banks of capacitors.

9. The circuit of claim 1, wherein the state machine further includes a third input terminal and the tuning circuit further includes a comparator having first and second input terminals and an output terminal, the first input terminal coupled for receiving a first reference potential, the second input terminal coupled to the first input terminal of the voltage controlled oscillator, and the output terminal coupled to the third input terminal of the state machine.

10. A tuning circuit, comprising:
a phase frequency detector having a plurality of input terminals and a plurality of output terminals;
a filter having an input terminal and an output terminal, the input terminal coupled to a first output terminal of the plurality of output terminals;
a voltage controlled oscillator having first and second input terminals and an output terminal, the first input terminal coupled to the output terminal of the filter;
a divide by n circuit coupled between the output terminal of the voltage controlled oscillator and a first input terminal of the plurality of input terminals of the phase frequency detector; and
a state machine coupled between the phase frequency detector and the voltage controlled oscillator.

11. The tuning circuit of claim 1O, wherein the state machine has a plurality of input terminals and a plurality of output terminals, the tuning circuit further including a switch having a control terminal and first and second current carrying electrodes, the control terminal coupled to a first output terminal of the plurality of output terminals of the state machine, the first current carrying electrode coupled for receiving a first reference voltage, and the second current carrying electrode coupled to the first input terminal of the voltage controlled oscillator.

12. The tuning circuit of claim 10, wherein the state machine has a plurality of input terminals and a plurality of output terminals, and wherein the voltage controlled oscillator includes at least one bank of capacitors, wherein a first bank of capacitors of the at least one bank of capacitors is coupled to a first output terminal of the plurality of output terminals of the state machine.

13. The tuning circuit of claim 10, wherein the state machine has a plurality of input terminals and a plurality of output terminals, and wherein the voltage controlled oscillator includes a plurality of banks of capacitors, wherein each output terminal of the plurality of output terminals of the state machine is coupled to a corresponding bank of capacitors of the plurality of banks of capacitors.

14. The tuning circuit of claim 10, wherein the state machine has a plurality of input terminals and a plurality of output terminals, the tuning circuit further including a switch having a control terminal and first and second current carrying electrodes, the control terminal coupled to a first output terminal of the plurality of output terminals of the state machine, the first current carrying electrode coupled for receiving a first reference voltage, and the second current carrying electrode coupled to the input terminal of the filter.

15. The tuning circuit of claim 10, wherein the state machine has a plurality of input terminals and a plurality of output terminals, the tuning circuit further including a comparator having first and second input terminals and an output terminal, the first input terminal coupled for receiving a first reference voltage, the second input terminal coupled to the first input terminal of the voltage controlled oscillator, and the output terminal coupled to a first input terminal of the state machine.

16. The tuning circuit of claim 10, wherein the phase frequency detector comprises a phase error detector coupled to a charge pump and wherein an output terminal of the charge pump serves as the first output terminal of the phase frequency detector.

17. A method for tuning a circuit, comprising:
generating the tuning voltage;
using the tuning voltage to drive an oscillator to generate an output signal having an output frequency;
forming a feedback signal from the output signal, the feedback signal having a frequency that is different from the output frequency of the output signal;
comparing the frequency of the feedback signal with a reference frequency;
switching out at least one bank of capacitors if the reference frequency is faster than the frequency of the feedback signal; and
switching in at least one bank of capacitors if the reference frequency is slower than the frequency of the feedback signal.

18. The method of claim 17, further including using a reference voltage to generate the tuning voltage.

19. The method of claim 18, further including opening a switch to switch out the reference voltage if the reference frequency is substantially equal to the frequency of the feedback signal.

20. The method of claim 18, further including, after switching out at least one bank of capacitors if the reference frequency is faster than the frequency of the feedback signal or switching in at least one bank of capacitors if the reference frequency is slower than the frequency of the feedback signal, updating the frequency of the feedback signal;
comparing the updated frequency of the feedback signal with the reference frequency;
switching out at least one bank of capacitors if the reference frequency is faster than the updated frequency of the feedback signal; and
switching in at least one bank of capacitors if the reference frequency is slower than the updated frequency of the feedback signal.

21. A method for tuning a circuit, comprising:
generating a tuning voltage;
comparing the tuning voltage with a reference voltage;
switching out one bank of capacitors if the tuning voltage is greater than the reference voltage; and
switching in one bank of capacitors if the tuning voltage is less than the reference voltage.

22. The method of claim 21, further including disabling a state machine if the tuning voltage substantially equals the reference voltage.

23. The method of claim 22, further including, after switching out one bank of capacitors if the tuning voltage is greater than the reference voltage or switching in one bank of capacitors if the tuning voltage is less than the reference voltage,
updating the tuning voltage;
comparing the updated tuning voltage with the reference voltage; and
switching in another bank of capacitors if the updated tuning voltage is greater than the reference voltage or switching out another bank of capacitors if the updated turning voltage is less than the reference voltage.
